(19) United States
(12) Patent Application Publication
(10) Pub. No.: US 2007/0105312 A1
(43) Pub. Date: May 10, 2007

(54) MEMORY CELL WITH NANOCRYSTAL AS DISCRETE STORAGE ELEMENT

(76) Inventor: Kyu S. Min, San Jose, CA (US)

Correspondence Address: George Chen;Blakely, Sokoloff, Taylor & Zafman LLP, Seventh Floor, 12400 Wilshire Boulevard, Los Angeles, CA, 90025-1030, US

(21) Appl. No.: 11/615,862

(22) Filed: Dec. 22, 2006

Related U.S. Application Data
(62) Division of application No. 10/997,609, filed on Nov. 23, 2004.

(51) Int. Cl. H01L 21/336; H01L 29/76

(52) U.S. Cl. 438/257; 257/314

(57) ABSTRACT

A memory cell including: a substrate; a channel region located in the substrate; a tunnel dielectric located over the channel region; and nanocrystals located over the tunnel dielectric.

### FIELD OF THE INVENTION

Embodiments of the present invention relate generally to semiconductor devices and more particularly to processes for forming semiconductor memory devices.

### BACKGROUND OF THE INVENTION

As semiconductor scaling continues, problems are being encountered which can affect semiconductor device performance and reliability. For non-volatile memory (NVM) devices, such as electrically erasable programmable read-only memory (EEPROM) devices, the leakage of charge stored in the memory cell's floating gate can be a problem due to thinning of the gate's tunnel dielectric layer.

Discrete storage element (nanocrystal) memory gates are one alternative being considered to replace conventional floating gates in scaled NVM devices. These gates use isolated semiconductive or conductive (e.g., silicon or metal) nanocrystals as discrete storage elements to store the floating gate's charge. The isolated nature of the nanocrystals reduces the floating gates vulnerability to charge leakage that can result from defects in the tunnel dielectric layer. Instead of providing a leakage path for the entire floating gate, the defect(s) provide a leakage path only for individually charged nanocrystals. Typically, the charge leakage from a single nanocrystal will not affect the overall charge of the floating gate.

Important considerations with respect to nanocrystal fabrication include the density of nanocrystals and the uniformity of the nanocrystal electronic tunneling distance. Higher nanocrystal densities (i.e. higher numbers of nanocrystals per memory cell) are preferred as they lead to an increased change in the threshold voltage (and therefore an increase in the programming window) and less overall variability in the distribution of threshold voltages across the memory array. Uniform tunneling distances (i.e., the range of distances from each nanocrystal to the silicon channel) are preferred because they facilitate reproducible charging and discharging of the floating gate.

Conventional methods for forming nanocrystals include (1) nucleation and growth from direct deposition of reactant species via chemical vapor deposition (CVD), evaporation, or physical vapor deposition (PVD); and (2) ion-implantation of impurities into a dielectric medium followed by thermal precipitation to form nanocrystals suspended in the medium.

Using direct deposition to nucleate and grow reactant species, one can form a layer of nanocrystals directly over a dielectric layer. This method enables nanocrystals to be fabricated in such as way as to have very uniform tunneling distances. However, this method is limited with respect to its ability to produce high nanocrystal densities. Therefore, the density of nanocrystals formed using CVD methods may be too low (˜<1E12/cm²) to adequately control the threshold voltage distribution of memory devices with critical dimensions in the sub-65 nanometer regime.

Using ion-implantation to introduce impurities (e.g., silicon) into a dielectric medium followed by an annealing process to precipitate nanocrystals in the dielectric medium is another technique for forming nanocrystals. Here, the density of nanocrystals can easily be controlled by varying the dose of the implanted species. However, because tunneling distance is now a function of the entire distribution of impurities implanted into the dielectric medium, significant limitations are imposed on the ability to control tunneling distance uniformity.

### BRIEF DESCRIPTION OF THE DRAWINGS

FIG. 1 illustrates a block diagram showing a process flow that incorporates an embodiment of the present invention;

FIGS. 2-7 illustrate cross-sectional views showing Fabrication of a storage device in accordance with an embodiment of the present invention.

It will be appreciated that for simplicity and clarity of illustration, elements in the drawings have not necessarily been drawn to scale. For example, the dimensions of some of the elements may be exaggerated relative to other elements for clarity. In other instances, well known features may be omitted or simplified in order not to obscure embodiments of the present invention. Further, where considered appropriate, reference numerals have been repeated among the drawings to indicate corresponding or analogous elements.

### DETAILED DESCRIPTION

In the following detailed description, a method for forming a semiconductor storage device is disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

In accordance with an embodiment of the present invention, a method of forming a storage device is disclosed wherein a sacrificial (removable material) layer is formed over a substrate, impurities are introduced into the sacrificial layer, the substrate is annealed to precipitate nanocrystals in the sacrificial layer, the sacrificial layer is removed without substantially removing the nanocrystal precipitates, and then a control dielectric layer is formed over the nanocrystal precipitates.

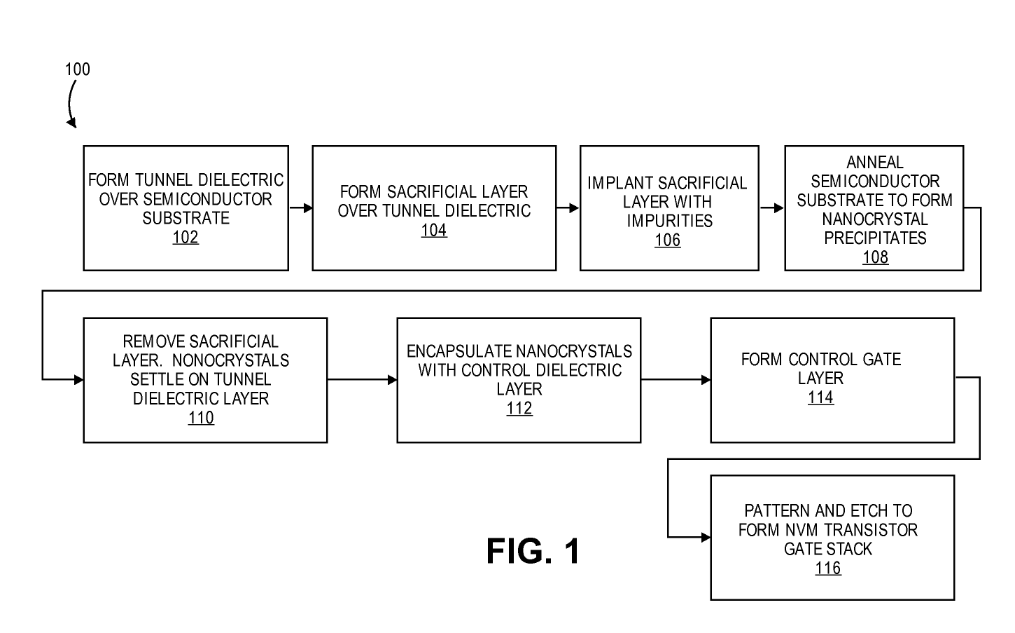

Shown in FIG. 1, is a flow diagram 100 describing formation of an NVM gate stack in accordance with an embodiment of the present invention. In 102 a tunnel dielectric layer is formed over a semiconductor substrate. In 104, a sacrificial layer is formed over the tunnel dielectric layer. In 106, the sacrificial layer is implanted with impurities. In 108, the substrate is annealed to promote formation of nanocrystal precipitates from the implanted impurities. In, 110 the sacrificial layer is selectively removed with respect to the nanocrystals. Remaining nanocrystals settle on the tunnel dielectric layer and form a floating gate layer. In 112, a control dielectric layer is formed over the floating gate layer. In 114, a control gate layer is formed over the control dielectric layer, and in 116 the stack of layers that includes the tunnel dielectric layer, the floating gate layer, the control dielectric layer, and the control gate layer is patterned and etched to form an NVM transistor gate stack.

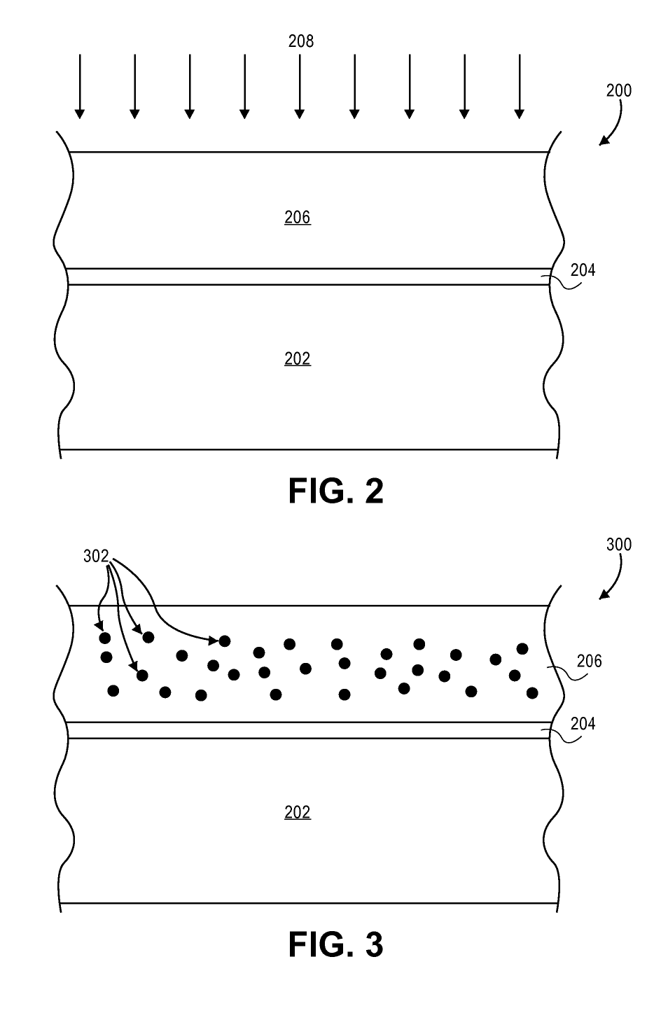

Embodiments of the present invention advantageously incorporate the strengths of using ion-implantation to form the nanocrystals (i.e., the ability to generate high nanocrystal densities) without having to endure its limitations (i.e., poor electron tunneling distance uniformity). In other words, using embodiments disclosed herein, nanocrystal electron tunneling distance uniformity becomes independent of the distribution of species implanted into the sacrificial layer and becomes a function of the tunnel dielectric layer thickness and/or uniformity. Therefore, high density nanocrystal floating gates that have tunneling distance uniformities typically only obtainable using CVD methods can be formed using ion implantation methods. These embodiments, their benefits, as well as variations thereof may be better understood with respect to FIGS. 2-7 discussed below.

A sequence of processing steps will now be discussed that describe in more detail the formation of the semiconductor device gate stack 116 discussed in FIG. 1. Shown in FIG. 2, is a cross section view of a partially fabricated semiconductor device 200 that includes a semiconductor substrate 202, a tunnel dielectric layer 204, a sacrificial layer 206, and species 208 being implanted into the sacrificial layer 206.

In accordance with one embodiment, the semiconductor substrate 202 is a monocrystalline semiconductor substrate, such as a silicon substrate. Alternatively, the semiconductor substrate 202 can be a compound semiconductor substrate, a silicon-on-insulator substrate or any other substrate used in the manufacture of semiconductor devices.

The tunnel dielectric layer 204 is formed over the semiconductor substrate 202. The tunnel dielectric layer 204 can include dielectric materials such as silicon dioxide, silicon nitride, hafnium oxide, zirconium oxide, tantalum pentoxide, or the like. In accordance with one embodiment, the tunnel dielectric layer 204 is a silicon dioxide containing material formed using a conventional thermal oxidation process. Alternative deposition processes can be used to form the tunnel dielectric layer 204 depending on the dielectric material being deposited. These deposition methods can include chemical vapor deposition, atomic layer deposition (ALD), or the like. Chemical vapor deposition processes as used herein can refer to low pressure CVD (LPCVD), atmospheric pressure CVD (APCVD), plasma enhanced CVD (PECVD), or the like.

A sacrificial layer 206 is formed over the tunnel dielectric layer 204. Typically, the material used to form the sacrificial layer 206 is an inorganic dielectric material such as silicon dioxide that has been formed using CVD. However, any suitable material (i.e. one that can be implanted, used to nucleate nanocrystals, and then selectively removed relative to the nanocrystals and if necessary the tunnel dielectric) regardless of whether it is an inorganic or organic material or whether it is deposited using CVD or spin-on methods can be used to form the sacrificial layer 206.

To the extent that the tunnel dielectric layer 204 and the sacrificial layer 206 comprise similar materials (e.g., both comprise silicon dioxide) then forming the tunnel dielectric layer 204 and the sacrificial layer 206 using different types of processes (e.g., forming the tunnel dielectric using a thermal oxidation process and forming the sacrificial layer using a CVD or spin-on process) may facilitate subsequent selective removal of the sacrificial layer 206 relative to the tunnel dielectric 206. Alternatively, intervening layer(s), such as for example a silicon nitride layer, may be positioned between the tunnel dielectric layer 204 and the sacrificial layer 206 to facilitate subsequent selective removal of the sacrificial layer 206.

The thickness of the sacrificial layer 206 can be determined by the implant profile. Implant profile refers to how implanted species (impurities used to form nanocrystals) are distributed throughout the sacrificial layer 206 following the implant process. In general, for a homogeneous implantation medium (such as in this case, the single sacrificial layer 206), a single implant process produces an implant profile having a Gaussian distribution, with the highest impurity concentration at the center of distribution and the lowest impurity concentration at the tails of the distribution. In one embodiment, the thickness of the sacrificial layer 206 is such that the center of the Gaussian distribution is at a point approximately halfway through the thickness of the sacrificial layer 206. The implantation profile (and dose) can be an important consideration when it comes to controlling the size and density of subsequently formed nanocrystals.

As shown in FIG. 2, the sacrificial layer 206 is implanted with ions 208. This forms a super saturated solid solution comprising the implanted species within the sacrificial layer 206. The ions 208 function as nucleation sources for subsequent nanocrystal formation. In embodiments where the subsequently formed nanocrystals comprise silicon, the implanted ions 208 can be silicon ions, such as ²⁸Si ions. The implant profile is a function of the dose and energy of the implanted species and the composition of the sacrificial layer 206. The implant dose and energy can be customized to yield specific nanocrystal densities and distributions. For example, for a given implantation energy, implantation of higher implant doses can result in higher nanocrystal densities, larger average diameter nanocrystals, or both.

Multiple implants at different energies and/or doses can also be used to produce relatively constant impurity concentrations throughout a greater range of thickness of the sacrificial layer 206 (or alternatively, to produce bimodal, trimodal, etc., impurity concentration distributions within the sacrificial layer 206) in order to produce a higher nanocrystal yield (higher overall number of nanocrystals), higher nanocrystal size uniformity (greater number of nanocrystals within a certain size range), or both. Additionally, to the extent that the nanocrystals are to be formed using materials other than silicon, ions corresponding to those other materials can be used as the species for implantation into the sacrificial layer, either as a sole element or as part of a compound (for example, in the case of compound semiconductor nanocrystals, using gallium and arsenic impurities to form gallium arsenide).

Following implantation, the partially fabricated semiconductor device 200 shown in FIG. 2 is annealed. Optimal anneal conditions (temperature, time, ambient atmosphere) can depend on nanocrystal size and density requirements. In general, higher anneal temperatures and longer anneal times result in larger average size nanocrystals. Nanocrystal densities, however, typically peak at a given temperature. This is because after a certain point, extensive particle coarsening (Ostwald ripening) leads to a reduction in nanocrystal density. In one embodiment, where silicon precipitates are used to form nanocrystals in a silicon dioxide containing sacrificial layer, anneal temperatures in a range of approximately 800° C.-1100° C. can be used to produce the nanocrystals.

Ref erring now to FIG. 3, the annealing process causes the implanted silicon ions to group together through phase separation and thereby forms silicon nanocrystals 302 within the sacrificial layer 206. As a result of annealing, nanocrystals 302 precipitate out of the super-saturated solid solution and become suspended in the sacrificial layer 206. The distribution of the nanocrystals 302 is determined by the initial distribution of implanted species in the sacrificial layer 206 as well as the anneal time and temperature.

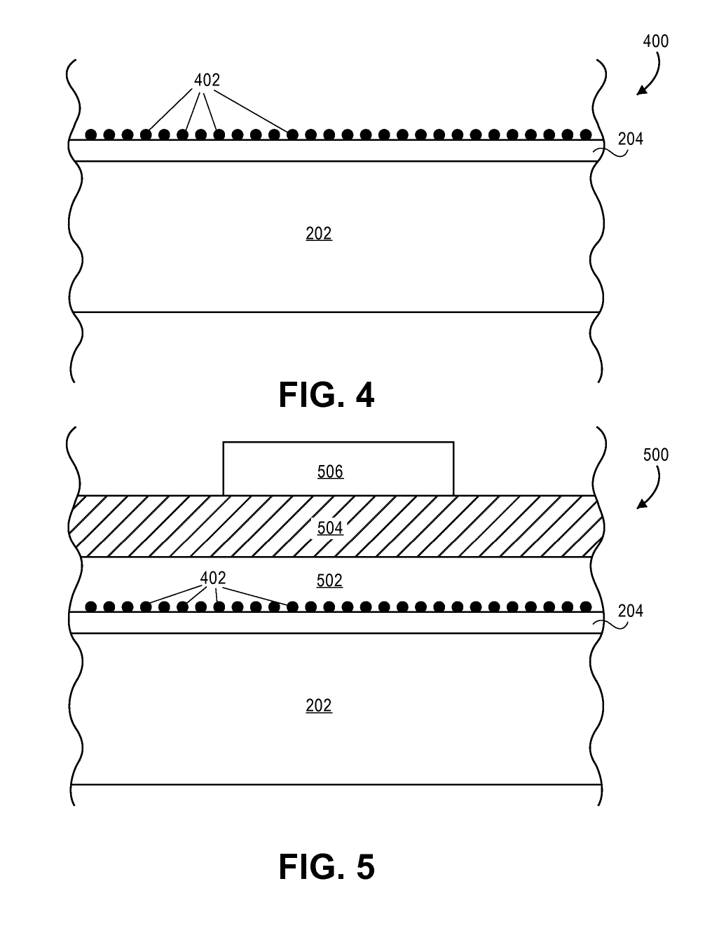

In accordance with one embodiment of the present invention, the sacrificial layer 206 is then selectively removed, as shown in FIG. 4. In embodiments where the nanocrystals include silicon and the sacrificial layer 206 is a silicon-dioxide based material, the sacrificial layer can be selectively removed using a dilute hydrofluoric (HF) acid solution. The dilute HF selectively etches the sacrificial layer 206 relative to the silicon nanocrystals 402. The substrate can be positioned horizontally during removal of the sacrificial layer and/or agitated at a rate that does not substantially displace nanocrystals removed from the sacrificial layer 206. In this way, the freed nanocrystals (i.e., nanocrystals that are no longer suspended in the sacrificial layer 206 because the sacrificial layer 206 has been etched away) can settle toward and then over or on the tunnel dielectric layer 204. After removal of the sacrificial layer 206, the nanocrystals 402 overlie the surface of the tunnel dielectric layer 204 (or an intervening layer, if present) in a random manner and thereby form a layer of floating gate nanocrystals 402.

The surfaces of the nanocrystals 402, as a result of being exposed to the dilute HF solution, can be terminated with hydrogen atoms. Hydrogen termination can advantageously reduce/prevent nanocrystal oxidation at temperatures lower than approximately ˜400 C, thereby reducing/minimizing undesired nanocrystal size reduction. In addition, at this point, the surface of the nanocrystals, the tunnel oxide, or both can be modified thru solvent exchange to terminate the surfaces with ligands that have functional groups capable of enhancing nanocrystal properties.

As shown in FIG. 4, the floating gate nanocrystals 402 are uniformly distributed over the tunnel dielectric layer 204 in such a manner that each nanocrystal 402 is substantially equidistant from the semiconductor substrate 202 (and the semiconductor device's channel region). If at this point, size reduction of the nanocrystals and/or the formation of a nanocrystal oxide shell is desired, these modifications can be achieved using various means known to one of ordinary skill (e.g., reactive oxygen, thermal oxidation, etc.).

As shown in FIG. 5, after forming the nanocrystals 402 over the tunnel dielectric 204, a control dielectric layer 502 is formed over the nanocrystals 402. In accordance with one embodiment, the control dielectric layer 502 is an undoped CVD oxide layer. Alternatively, the control dielectric layer 502 can be formed using other deposition processes and can include other dielectric materials or combinations of dielectric materials, such as an oxide-nitride-oxide (ONO) film stack, or the like. The formation of the control dielectric layer 502 is considered conventional to one of ordinary skill in the art.

Formed over the control dielectric layer 502 is a control gate layer 504. In one embodiment, the control gate layer 504 is a CVD deposited polysilicon layer. The polysilicon can be doped in-situ with a p-type dopant (or an n-type dopant depending of the type of semiconductor device formed) or, if desired, during subsequent processing using ion implantation. In addition, subsequent processing can optionally include salicidation of the polysilicon.

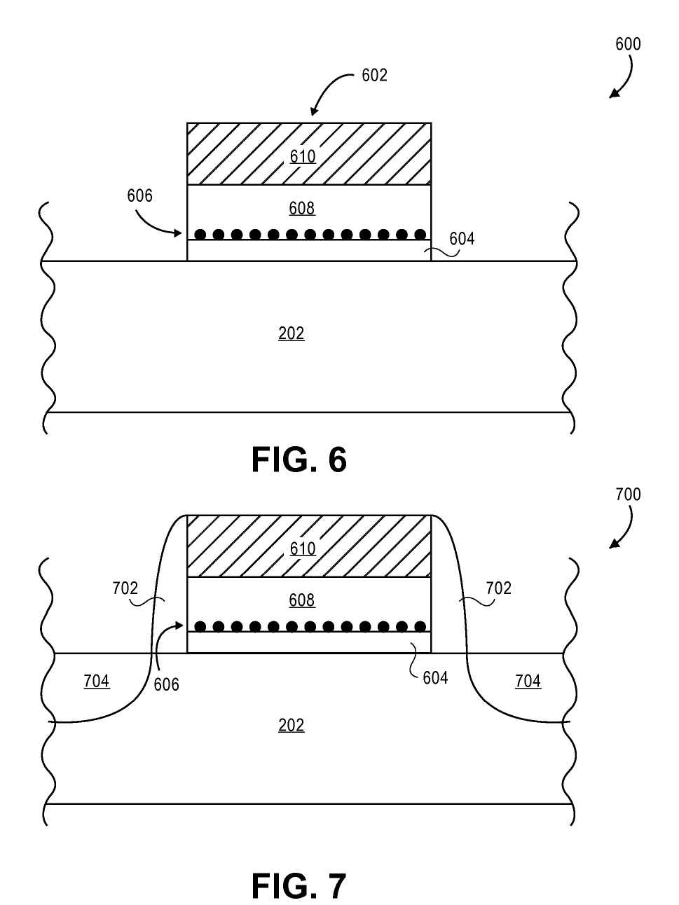

After depositing the control gate layer 504, the substrate is patterned with resist 506. Then, the patterned stack of layers comprising the tunnel dielectric layer 204, the floating gate nanocrystals 402, the control dielectric layer 502 and the control gate 504 are etched to substantially form the non-volatile memory gate stack 602 shown in FIG. 6.

The patterned stack of layers can be etched using a conventional silicon reactive ion etch (RIE) process to first remove exposed portions of control gate layer 504 and thereby expose the control dielectric layer 502. The exposed portions of the control dielectric layer 502 can then be removed either in-situ (immediately following the etch of the control gate layer 504 in the same chamber) or alternatively by removing the wafer from the silicon RIE etcher and then etching the control dielectric layer 502 using a wet or dry dielectric etch process. Etching portions of the control dielectric layer will expose the nanocrystals 402. The resist layer 506 can be removed (if it has not already been removed). The exposed nanocrystals 402 can then be processed through a polysilicon reoxidation process that heats the partially fabricated semiconductor device 600 in an oxygen ambient. This process is considered conventional to one of ordinary skill.

The reoxidation process forms a thin layer of silicon dioxide on the unremoved portions of polysilicon control gate 610 and also converts silicon nanocrystals 402 that are exposed to the ambient environment (i.e. not positioned between the unremoved portions of the control gate layer 504 and the tunnel dielectric layer 204) to silicon dioxide. Then, the oxidized nanocrystals, any remaining control dielectric layer 502, and the tunnel dielectric layer 204 can be removed using a conventional dielectric etch process to form the NVM gate stack 602 shown in FIG. 6. The NVM gate stack 602 comprises a control gate 610 overlying a control dielectric 608, overlying the nanocrystal floating gate 606, overlying the tunnel dielectric 604.

FIG. 7 illustrates a cross-sectional view of the NVM gate stack of FIG. 6 after spacers 702 and source and drain regions 704 have been formed to substantially form a transistor structure 700 (or at least a substantial portion thereof). The spacers 702 can be formed using conventional methods whereby a dielectric material such as silicon nitride is deposited over the surface of the partially fabricated semiconductor device 600. Then, portions of the nitride layer are removed using a conventional anisotropic nitride spacer etch process until side wall spacers 702 are formed along sidewalls of the NVM gate stack. The source and drain regions 704 can be formed via implantation of dopant materials in the semiconductor substrate 202 after the spacers 702 are formed using conventional implant and anneal processing. Formation of the source and drain regions 704 results in the formation of a channel region that lies beneath the tunnel dielectric 604. Such a transistor structure may additionally include source/drain extension regions (not shown) between the source/drain and channel regions as well as isolation regions (not shown) to isolate the transistor from neighboring devices. The transistor structure 700 shown in FIG. 7 can subsequently be processed using any combination of standard or non-standard processes to form a semiconductor device integrated circuit.

Transistors structures disclosed herein may be used in flash memories, EEPROM memories, DRAM memories, or other memory structures of varying volatility. In particular, such a transistor structure may be useful in the production of flash memory structures that need the state of the transistor to be maintained for extended periods of time.

Embodiments of the present invention permit the formation of high nanocrystal density floating gates. Because ion implantation is used to introduce impurities that subsequently form the nanocrystals, high nanocrystal densities are possible. However, unlike prior art implant methods, which can have unacceptably high electron tunnel distance non-uniformities, the embodiments disclosed herein allow precise placement of the nanocrystals. By removing the medium in which the nanocrystals are suspended and then allowing them to settle onto the underlying tunnel dielectric layer, the nanocrystal electron tunneling distance can be controlled precisely to the extent that the underlying tunnel dielectric thickness and/or uniformity can be controlled (using state of the art deposition methods, thickness/uniformity control can be on the order of angstroms).

This represents a significant improvement over prior art implant and CVD methods, neither of which can provide both high densities and high tunneling uniformities. Here, electron densities are not subjected to the theoretical area limitation of less than approximately 1E12 nanocrystals/cm² imposed by direct deposition CVD methods. Therefore, electron densities close to the theoretical values, on the order of 1E13/cm² can be produced for ˜3 nanometer nanocrystals (one of ordinary skill appreciates that nanocrystal density limitations are impacted by the size of the nanocrystals and therefore as the size of the nanocrystal increases above 3 nanometers, the theoretical density limitation will correspondingly decrease). Also, electron tunneling distance is no longer a function of the implant profile in the sacrificial layer. Instead, it is a function of the thickness and uniformity of the tunnel dielectric, parameters which are highly controllable. Because the nanocrystals settle over the tunnel dielectric, they are substantially equidistant from the channel region associated with the floating gate. Moreover, because no elaborate chemicals, films, or processes are required to carry out embodiments of the present invention, processes that incorporate one or more of the embodiments herein can be integrated into existing semiconductor manufacturing lines with relative ease.

The various implementations described above have been presented by way of example only and not limitation. Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A nanocrystal floating gate having a nanocrystal density greater than 1E13 nanocrystals per squared centimeter wherein a tunneling distance uniformity of nanocrystals overlying a tunnel dielectric is a function of the thickness and uniformity of tunnel dielectric.

2. The nanocrystal floating gate of claim 1, wherein the nanocrystals are substantially equidistant from a channel region associated with the nanocrystal floating gate.

3. The nanocrystal floating gate of claim 1, wherein the nanocrystals are on the tunnel dielectric.

4. The nanocrystal floating gate of claim 1, further comprising an intervening layer between the tunnel dielectric and the nanocrystals.

5. A memory cell comprising:
a substrate;
a channel region disposed in the substrate;
a tunnel dielectric disposed over the channel region; and
nanocrystals disposed over the tunnel dielectric.

6. The memory cell of claim 5 wherein the nanocrystals comprise a size of 3 nanometers.

7. The memory cell of claim 6 wherein the nanocrystals comprise a density of 1E13/cm2.

8. The memory cell of claim 7 wherein the nanocrystals are disposed equidistant from the channel region.

9. The memory cell of claim 5 wherein the tunnel dielectric comprises silicon nitride.

10. The memory cell of claim 5 wherein the tunnel dielectric comprises hafnium oxide.

11. The memory cell of claim 5 wherein the tunnel dielectric comprises zirconium oxide.

12. The memory cell of claim 5 wherein the tunnel dielectric comprises tantalum pentoxide.

13. The memory cell of claim 5 wherein the nanocrystal is semiconductive.

14. The memory cell of claim 5 wherein the nanocrystal is conductive.

15. The memory cell of claim 5 wherein the nanocrystals comprise a very uniform tunneling distance.

16. The memory cell of claim 5 wherein the substrate comprises a compound semiconductor.

17. The memory cell of claim 5 wherein the substrate comprises a silicon-on-insulator.

18. The memory cell of claim 5 further comprising an intervening layer between the tunnel dielectric and the nanocrystals.
